(19) United States
(12) Patent Application Publication
(10) Pub. No.: US 2023/0104222 A1
(43) Pub. Date: Apr. 6, 2023

(54) FLOW-RATE MEASURING DEVICE

(71) Applicant: AZBIL CORPORATION, Tokyo (JP)

(72) Inventors: Wataru HASEBE, Chiyoda-ku (JP); Kei SUZUKI, Chiyoda-ku (JP); Shinsuke MATSUNAGA, Chiyoda-ku (JP)

(73) Assignee: AZBIL CORPORATION, Tokyo (JP)

(21) Appl. No.: 17/957,130

(22) Filed: Sep. 30, 2022

(30) Foreign Application Priority Data
Oct. 1, 2021 (JP) 2021-162618

(51) Int. Cl. H01L 21/67

(52) U.S. Cl. CPC H01L 21/67253

(57) ABSTRACT

A mass flow controller includes a display unit; an operation unit; a basic functional section that realizes a basic function as the mass flow controller; a display control unit that causes the display unit to display a screen in an orientation corresponding to an instruction on an orientation from an operator; a layout-orientation setting unit that sets the vertical direction of the function layout of the operation unit to match the vertical direction of display by the display unit; and an orientation-instruction acquiring unit that acquires an instruction to specify an orientation of display by the display unit or an orientation of the function layout of the operation unit.

### CROSS-REFERENCE TO RELATED APPLICATIONS

The present application is based on and claims priority to Japanese Application No. 2021-162618, filed Oct. 1, 2021, the entire contents of which are incorporated herein by reference.

### BACKGROUND

### 1. Field of the Disclosure

The present disclosure relates to a device, such as a flow-rate sensor and a mass flow controller, having a flow-rate measuring function.

### 2. Description of the Related Art

In semiconductor manufacturing apparatuses, a flow-rate measuring device and a flow-rate controlling device, such as a flow-rate sensor and a mass flow controller, are employed to introduce a material gas and the like at a fixed flow rate into a vacuum chamber (refer to Japanese Unexamined Patent Application Publication No. 2008-039588). FIG. 8 is a sectional view illustrating a configuration of a mass flow controller 10. In FIG. 8, the reference sign 1 denotes a body block, the reference sign 2 denotes a sensor package, the reference sign 3 denotes a head portion of the sensor package 2, the reference sign 4 denotes a flow-rate measuring unit (flow sensor), the reference sign 5 denotes a valve, the reference sign 6 denotes a flow path formed in the inside of the body block 1, the reference sign 7 denotes an opening on the inlet side of the flow path 6, and the reference sign 8 denotes an opening on the outlet side of the flow path 6.

A fluid flows into the flow path 6 through the opening 7, passes through the valve 5, and is discharged through the opening 8. At this time, the flow-rate measuring unit 4 measures the flow rate of the fluid. The flow-rate measuring unit 4 is mounted on the head portion 3 of the sensor package 2 and attached to the body block 1 so as to be exposed to the fluid to be measured. A control device (not illustrated) of the mass flow controller 10 compares a flow-rate measured value obtained by the flow-rate measuring unit 4 with a flow-rate set value, and, on the basis of a result of the comparison, outputs driving current to the valve 5. By thus driving the valve 5, the flow rate of the fluid is controlled to coincide with the flow-rate set value.

FIG. 9 is a sectional view illustrating a configuration of a vacuum device (for example, a plasma etching device) to be used in a semiconductor manufacturing apparatus. Such a vacuum device is disclosed in, for example, Japanese Unexamined Patent Application Publication No. 11-233507, Japanese Unexamined Patent Application Publication No. 2014-207353, and Japanese Unexamined Patent Application Publication No. 2018-006380. In FIG. 9, the reference sign 100 denotes a vacuum chamber, the reference sign 101 denotes an exhaust pipe provided at a bottom portion of the vacuum chamber 100, the reference sign 102 denotes a shower head functioning as an upper electrode, the reference sign 103 denotes a placement base functioning as a lower electrode, the reference sign 104 denotes a gas supply pipe connected to a gas introduction port of the shower head 102, the reference sign 105 denotes a pressure sensor provided in the vacuum chamber 100, and the reference sign 106 denotes a high-frequency power source. The gas supply pipe 104 is provided with the mass flow controller 10 described with reference to FIG. 8.

In the example of a vacuum device in FIG. 9, the atmosphere of the inside of the vacuum chamber 100 is exhausted through the exhaust pipe 101 to evacuate the inside to a predetermined vacuum degree, and a treatment gas is introduced to the shower head 102 through the gas supply pipe 104. The treatment gas is uniformly discharged through a plurality of discharge holes (not illustrated) provided in the shower head 102 to a wafer 107 placed on the placement base 103, and the pressure in the inside of the vacuum chamber 100 is maintained at a predetermined value. In this state, high-frequency electric power is applied from the high-frequency power source 106 to the placement base 103. Consequently, a high-frequency electric field is generated between the placement base 103 as the lower electrode and the shower head 102 as the lower electrode, and the treatment gas is dissociated into plasma. Etching is performed on the wafer 107 with the plasma.

Meanwhile, a flow-rate sensor and a mass flow controller are also used in industrial furnaces and the like in addition to semiconductor manufacturing apparatuses when highly accurate flow-rate control is required. In these fields of use, when a communication function is not used, an operator may perform work such as checking a flow rate via a human machine interface (HMI) included in a flow-rate sensor or a mass flow controller. In such a case, a flow-rate sensor or a mass flow controller that includes a HMI having excellent operability is required since operation of, for example, finally determining a display content of a display unit is required to be performed after installation in an industrial furnace.

FIG. 10 is an external view of a multifunctional-type mass flow controller including a display unit 11 and an operation unit 12. As described above, the reference sign 5 denotes the valve, the reference sign 7 denotes the opening on the inlet side of the flow path, and the reference sign 8 denotes the opening on the outlet side of the flow path.

Recent flow-rate sensors and mass flow controllers are multifunctional devices including an alert function in addition to a measurement function and a control function and are devices that require, for example, operation of a display content and the like after installed in an industrial furnace. Meanwhile, flow-rate sensors and mass flow controllers are devices that are directly installed in a pipe in which a fluid (gas or liquid) whose flow rate is to be measured and controlled flows. The flow-rate sensors and the mass flow controllers are thus not necessarily installed with priority given to convenience of operation while requiring operation. In other words, a circumstance in which convenience of operation is impaired may occur. Thus, improvement is desired.

### SUMMARY

The present disclosure has been made to solve the aforementioned circumstance, and an object of the present disclosure is to provide a flow-rate measuring device capable of improving convenience of operation after mounted.

A flow-rate measuring device according to the present disclosure includes a flow-rate measuring unit configured to measure a flow rate of a fluid that flows in a flow path; a display unit configured to display information relating to at least the flow-rate measuring unit; an operation unit configured to receive an operation input from an operator; an orientation-instruction acquiring unit configured to acquire an instruction to specify an orientation of display by the display unit or an orientation of a function layout of the operation unit; a display control unit configured to cause the display unit to display a screen in an orientation corresponding to the instruction on the orientation; and a layout-orientation setting unit configured to set a vertical direction of the function layout of the operation unit to match a vertical direction of the display by the display unit.

In one configuration example of the flow-rate measuring device according to the present disclosure, the display unit and the operation unit are disposed as separate components in regions that differ from each other. In one configuration example of the flow-rate measuring device according to the present disclosure, the display unit and the operation unit are constituted by one component having both a display function and an input function. In one configuration example of the flow-rate measuring device according to the present disclosure, the display control unit is capable of setting the orientation of the display by the display unit in units of 90° and is only allowed to set such that a flow direction of the fluid is opposite to the vertical direction of the display and such that the vertical direction of the display is orthogonal to the flow direction of the fluid. In one configuration example of the flow-rate measuring device according to the present disclosure, an opening on an inlet side of the flow path and an opening on an outlet side of the flow path are provided such that a set orientation in which a flow direction of the fluid is identical to the vertical direction of the display by the display unit is a set orientation that is not recommended in flow-rate measurement.

According to the present disclosure, due to including the orientation-instruction acquiring unit, the display control unit, and the layout-orientation setting unit, it is possible to set the orientation of display and the orientation of the function layout of the operation unit so as not to be an orientation that is difficult to be viewed by an operator and thus possible to improve convenience of operation after mounting of the flow-rate measuring device.

### BRIEF DESCRIPTION OF THE DRAWINGS

FIG. 1A, FIG. 1B, and FIG. 1C illustrate examples in which the orientations of a display unit and an operation unit of a mass flow controller are changed in the present disclosure;

FIG. 2A and FIG. 2B illustrate examples in which the orientations of the display unit and the operation unit are changed in accordance with the orientation of the mass flow controller in the present disclosure;

FIG. 3 illustrates an installation example in which the operation unit of the mass flow controller is on the upper side, and the display unit thereof is on the lower side;

FIG. 4 illustrates an orientation excluded from orientation change;

FIG. 5 is a block diagram illustrating a configuration of a mass flow controller according to an embodiment of the present disclosure;

FIG. 6 is a flowchart describing action of a display control unit, a layout-orientation setting unit, and an orientation-instruction acquiring unit of the mass flow controller according to an embodiment of the present disclosure;

FIG. 7 is a block diagram illustrating a configuration example of a computer that realizes the mass flow controller according to an embodiment of the present disclosure;

FIG. 8 is a sectional view illustrating a configuration of the mass flow controller;

FIG. 9 is a sectional view illustrating a configuration of a vacuum device; and

FIG. 10 is an external view of a multifunctional-type mass flow controller including a display unit and an operation unit.

### DETAILED DESCRIPTION

### Inventive Principle 1

Flow-rate sensors and mass flow controllers are devices that are directly installed in a pipe in which a fluid (gas or liquid) whose flow rate is to be measured and controlled flows. In these devices, a preferable flow direction such as, for example, the fluid flow direction of the fluid in the mass flow controller illustrated in FIG. 8 may be prescribed. Consequently, there may be a case in which the orientation of a HMI for operation has to be an orientation (inconvenient orientation) that is difficult to be viewed by an operator.

The inventor focused on such a circumstance in which the convenience of operation is impaired as described above, and conceived of setting a substantially equal aspect ratio of a display unit to thereby enable the orientation of display to be changed in units of 90° and limiting operation keys (the layout of the operation keys) to be capable of changing the orientation thereof in units of 90° in accordance with the orientation of display, thereby enabling an operator to select the orientation of the entirety of a HMI after a flow-rate sensor or a mass flow controller is installed, which can improve convenience.

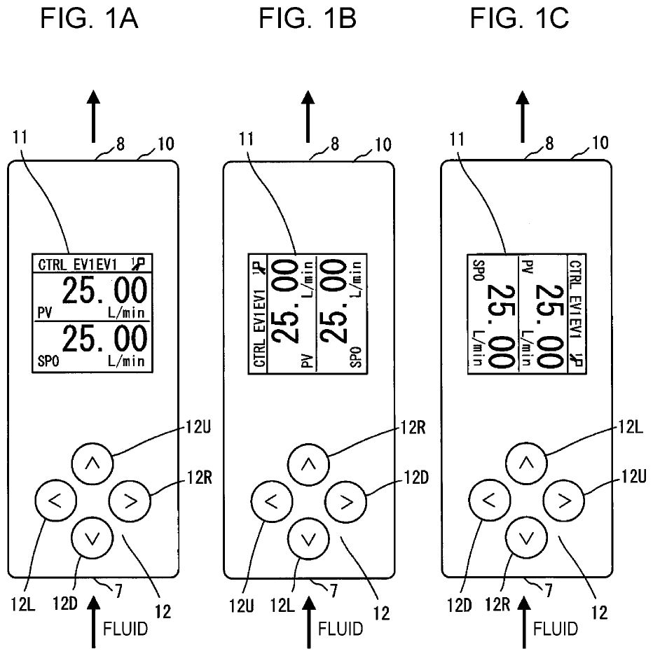

FIG. 1A, FIG. 1B, and FIG. 1C illustrate examples in which the orientations of the display unit 11 and the operation unit 12 are changed with the orientation of the mass flow controller 10 unchanged. The reference sign 12U denotes an up arrow key (for example, a key for increasing a set value), the reference sign 12D denotes a down arrow key (for example, a key for decreasing the set value), the reference sign 12L denotes a left arrow key (for example, a key for moving leftward by one digit in the set value), and the reference sign 12R denotes a right arrow key (for example, a key for moving rightward by one digit in the set value).

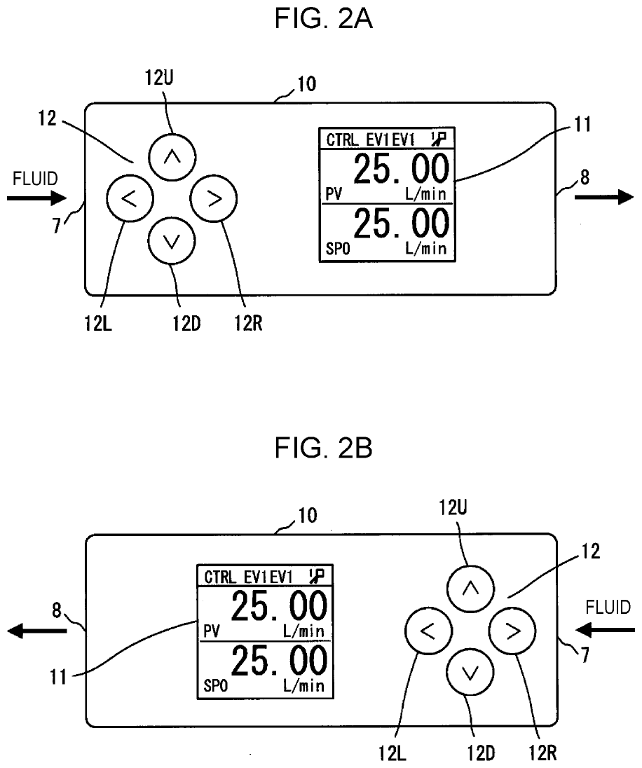

FIG. 2A and FIG. 2B illustrate examples in which the orientation of the display unit 11 is changed in accordance with the orientation of the mass flow controller 10. In the example in FIG. 2A, the left side is the inlet side of a flow path, and the right side is the outlet side of the flow path. In the example in FIG. 2B, the right side is the inlet side of the flow path, and the left side is the outlet side of the flow path.

### Inventive Principle 2

An operator who performs work of installation (for example, mounting on a semiconductor manufacturing apparatus) of a flow-rate sensor or a mass flow controller and an operator who actually performs operation such as parameter adjustment are not necessarily the same. In a case of the semiconductor manufacturing apparatus, such installation work and operation are generally performed by operators from different companies on different sites. In such a case, the operator who performs installation work may install the flow-rate sensor or the mass flow controller without considering the convenience of the operator who performs operation.

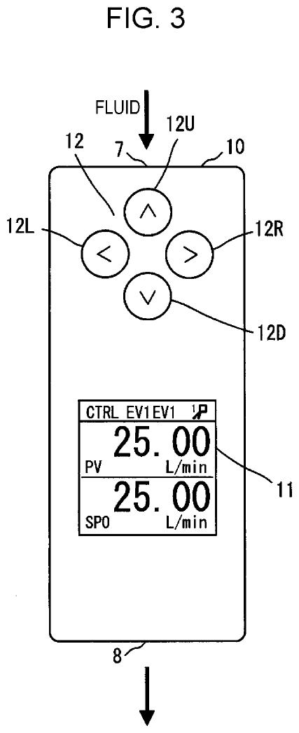

Specifically, the mass flow controller 10 may be installed such that the display unit 11 is on the lower side and the operation unit 12 is on the upper side as illustrated in, for example, FIG. 3. Although it is possible to change the orientation of the display unit 11 by the function described in the inventive principle 1, display becomes difficult to be viewed due to the hand of the operator covering the display unit 11 during operation.

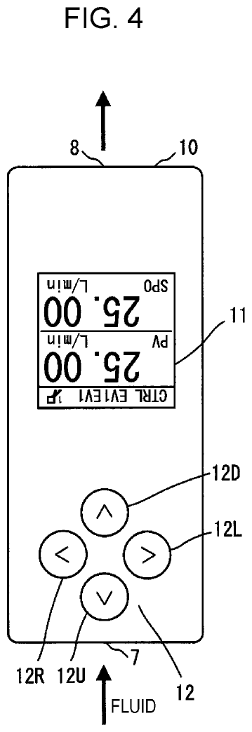

Focused on such inconvenience, the inventor conceived of limiting the orientations of the display unit and the operation unit (the layout of the operation keys) to the three orientations illustrated in FIG. 1A, FIG. 1B, and FIG. 1C. In other words, the orientation change in FIG. 4, which corresponds to FIG. 1A, FIG. 1B, and FIG. 1C, is intentionally set as impossible processing.

### Inventive Principle 3

When a flow-rate sensor or a mass flow controller is installed in a pipe extending in the longitudinal direction, there are a recommended orientation and a non-recommended orientation (for example, a case in which the flow direction in liquid flow-rate measurement is from the upper side toward the lower side of the pipe extending in the longitudinal direction and in which liquid does not fill the pipe and affects the accuracy of flow-rate measurement). In consideration of such restriction, it is suitable to assign the non-recommended orientation to the orientation in FIG. 4.

For example, it is suitable to design such that the flow direction of the fluid in the mass flow controller 10 in FIG. 2A and FIG. 2B coincides with the direction from the lower side toward the upper side in FIG. 1A. That is, device design such as that in FIG. 3 in which the flow direction of the fluid is the flow direction from the upper side toward the lower side of the pipe extending in the longitudinal direction is easily avoided.

When the flow-rate sensor is of a type in which the flow direction of the fluid is prescribed as with the mass flow controller, it is also suitable to design such that the flow direction coincides with the direction from lower side toward the upper side in FIG. 1A.

Thus, according to the present disclosure, it is possible to obtain an effect that setting in which display becomes difficult to be viewed is avoided as much as possible and that setting in a non-recommended orientation is avoided as much as possible. The inventive principle 3 may be employed together with the processing indicated in the inventive principle 2.

### Embodiment

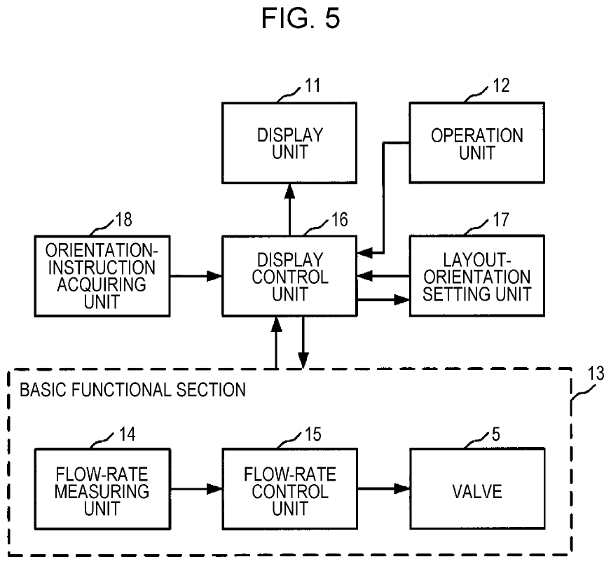

Hereinafter, an embodiment of the present disclosure will be described with reference to the drawings. FIG. 5 is a block diagram illustrating a configuration of a mass flow controller according to an embodiment of the present disclosure. In the present embodiment, a mass flow controller will be described as one example of a flow-rate measuring device. In addition, in the present embodiment, a configuration in which a combination of the inventive principle 2 and the inventive principle 3 is applied to a configuration corresponding to the aforementioned inventive principle 1 will be described.

The mass flow controller is constituted by the display unit 11 for displaying information such as a flow-rate measured value, a target flow rate (set value), a valve operation amount, and a control state; the operation unit 12 for receiving an operation input from an operator; a basic functional section 13 that realizes a basic function as the mass flow controller; a display control unit 16 that causes the display unit 11 to display a screen in an orientation corresponding to an instruction on an orientation from the operator; a layout-orientation setting unit 17 that sets the vertical direction of the function layout of the operation unit 12 to match the vertical direction of display by the display unit 11; and an orientation-instruction acquiring unit 18 that acquires an instruction to specify the orientation of the display by the display unit 11 or the orientation of the function layout of the operation unit 12.

The basic functional section 13 is constituted by the valve 5 provided in a flow path; a flow-rate measuring unit 14 that measures the flow rate of a fluid that flows in the flow path; and a flow-rate control unit 15 that controls the opening degree of the valve 5 such that the flow rate measured by the flow-rate measuring unit 14 coincides with a previously prescribed target flow rate.

In the present embodiment, it is suitable that the aspect ratio of a display region of the display unit 11 be a substantially equal aspect ratio. Specifically, the display region is preferably a square.

While the flow-rate control unit 15 of the basic functional section 13 controls the opening degree of the valve 5 on the basis of the flow rate measured by the flow-rate measuring unit 14 and the target flow rate, the action of the basic functional section 13 is the same as a conventional configuration disclosed in, for example, Japanese Unexamined Patent Application Publication No. 2008-039588. Thus, detailed description of the basic functional section 13 is omitted.

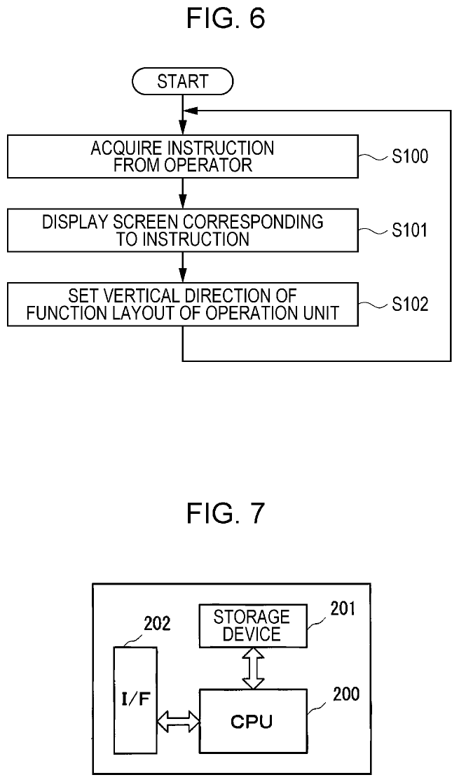

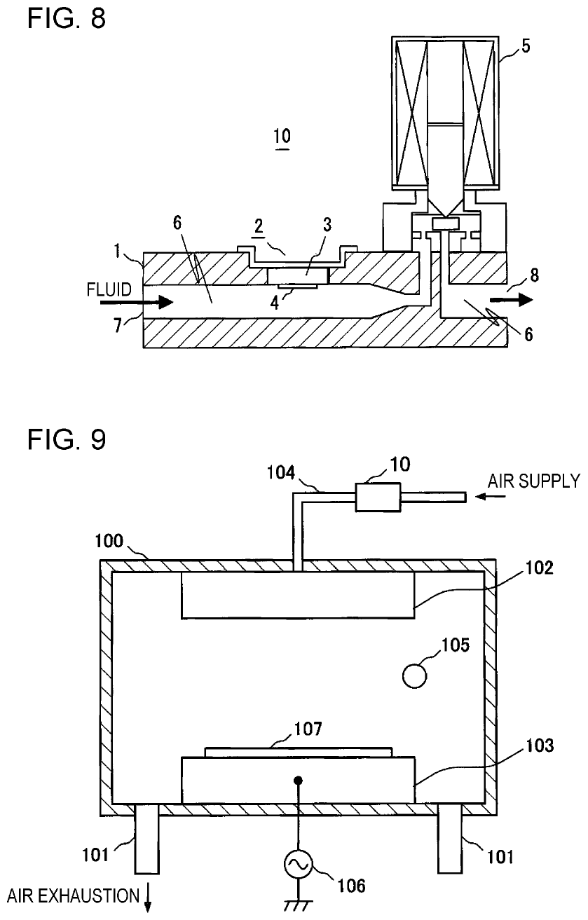

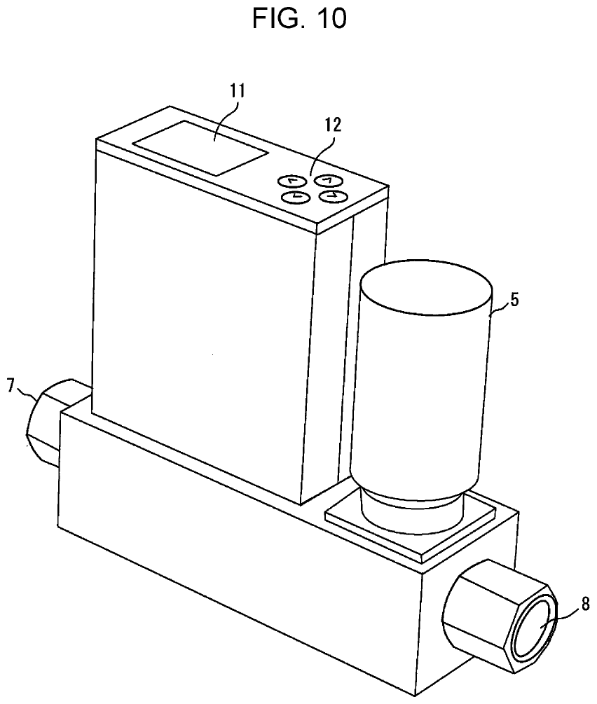

FIG. 6 is a flowchart describing the action of the display control unit 16, the layout-orientation setting unit 17, and the orientation-instruction acquiring unit 18.

The orientation-instruction acquiring unit 18 acquires an instruction to specify a display orientation of the display unit 11 or a layout orientation of the operation keys of the operation unit 12 from an operator (step S100 in FIG. 6). An operation key dedicated to specify turning of the display orientation and the layout orientation simply by rotation in units of 90° may be included, and a special operation (for example, long press, simultaneous press, or the like) with respect to the operation keys 12U, 12D, 12L, and 12R of the operation unit 12 may be acquired as an instruction from an operator.

Next, the display control unit 16 causes the display unit 11 to display a screen in an orientation corresponding to the orientation instruction from the operator (step S101 in FIG. 6). The orientation is set in units of 90°. However, it is not allowed to set such that, as illustrated in FIG. 4, the flow direction of the fluid is identical to the vertical direction (vertical direction of the function layout of the operation unit 12) from the upper side toward the lower side of display. Setting is limited to only setting in which the flow direction of the fluid is opposite to the vertical direction of display as illustrated in FIG. 1A and setting in which the vertical direction of display is orthogonal to the flow direction of the fluid as illustrated in FIG. 1B and FIG. 1C.

For example, in specifying a display orientation and a layout orientation in units of 90°, an operator is not allowed to select setting in the orientation in FIG. 4.

In addition, when the operator selects setting in the orientation in FIG. 4, the display control unit 16 may cause the display unit 11 to display a message indicating that setting is impossible.

The layout-orientation setting unit 17 sets the vertical direction of the function layout of the operation unit 12 to match the vertical direction of display set by the display control unit 16 (step S102 in FIG. 6). For example, in the example in FIG. 1A, the display control unit 16 recognizes that the operation key closest to the inlet side (the lower side in FIG. 1A, FIG. 1B, and FIG. 1C) of the flow path as the down arrow key 12D, the operation key positioned on the left and right sides in the flow direction of the fluid as the left arrow key 12L and the right arrow key 12R, and the operation key farthest from the inlet side of the flow path as the up arrow key 12U on the basis of the setting by the layout-orientation setting unit 17.

In the example in FIG. 1B, the display control unit 16 recognizes that the operation key closest to the inlet side of the flow path as the left arrow key 12L, the operation keys positioned in the direction orthogonal to the flow direction of the fluid as the up arrow key 12U and the down arrow key 12D, the operation key farthest from the inlet side of the flow path as the right arrow key 12R on the basis of the setting by the layout-orientation setting unit 17.

In the example in FIG. 1C, the display control unit 16 recognizes that the operation key closest to the inlet side of the flow path as the right arrow key 12R, the operation keys positioned in the direction orthogonal to the flow direction of the fluid as the up arrow key 12U and the down arrow key 12D, and the operation key farthest from the inlet side of the flow path as the left arrow key 12L on the basis of the setting by the layout-orientation setting unit 17.

Subsequently, the display control unit 16 recognizes the function layout of each operation key of the operation unit 12 in accordance with setting by the layout-orientation setting unit 17. For example, when an operation of changing setting of a parameter (for example, the PID parameter or the target flow rate) of the flow-rate control unit 15 is performed with respect to the operation unit 12 by an operator, the display control unit 16 sends a value after the change to the flow-rate control unit 15. As a result, the parameter of the flow-rate control unit 15 is updated. The display control unit 16 also causes the display unit 11 to display, for example, a flow-rate measured value received from the flow-rate control unit 15.

Consequently, convenience of operation after mounting of the flow-rate measuring device of the mass flow controller can be improved in the present embodiment. In the present embodiment, the opening 7 on the inlet side of the flow path and the opening 8 on the outlet side thereof are provided such that a set orientation in which the flow direction of the fluid is identical to the vertical direction of display is the set orientation that is not recommended in flow-rate measurement. In other words, when the flow direction is the direction from the lower side toward the upper side of a pipe extending in the longitudinal direction, a settable orientation of display is inversed as illustrated in FIG. 4. When the orientation of display is thus set as illustrated in FIG. 3 to be a preferable orientation, the flow direction becomes a direction from the upper side toward the lower side of the pipe extending in the longitudinal direction and becomes a direction that affects the flow-rate measurement accuracy. In other words, by determining settable orientations of display and formation positions of the openings 7 and 8 of the flow path as those in the present embodiment, it is possible to assign the orientation not recommended in flow-rate measurement to the orientation in FIG. 3. and FIG. 4.

The present embodiment has been described in a form including the operation unit 12, which is constituted by mechanical components, in a region that differs from a region where the display unit 11 is provided. The present disclosure is, however, also applicable to a case in which the display unit 11 and the operation unit 12 are constituted by one component by employing, for example, a touch panel such as that of a smartphone.

In the present disclosure, the flow-rate control function is not an essential constituent feature. The present disclosure may be also applicable to a flow-rate sensor having only the flow-rate measuring function.

The flow-rate control unit 15, the display control unit 16, the layout-orientation setting unit 17, and the orientation-instruction acquiring unit 18 in the present embodiment can be realized by a computer that includes a central processing unit (CPU), a storage device, and an interface, and a program that controls these hardware resources. FIG. 7 illustrates a configuration example of the computer.

The computer includes a CPU 200, a storage device 201, and an interface device (I/F) 202. The flow-rate measuring unit 4, the valve 5, the display unit 11, the operation unit 12, and the like are connected to the I/F 202. In such a computer, a program for realizing the method of the present disclosure is stored in the storage device 201. The CPU 200 executes the processing described in the present embodiment in accordance with the program stored in the storage device 201.

The present disclosure is applicable to a flow-rate sensor or a mass flow controller.

What is claimed is:

1. A flow-rate measuring device comprising:
a flow-rate measuring unit configured to measure a flow rate of a fluid that flows in a flow path;
a display unit configured to display information relating to at least the flow-rate measuring unit;
an operation unit configured to receive an operation input from an operator;
an orientation-instruction acquiring unit configured to acquire an instruction to specify an orientation of display by the display unit or an orientation of a function layout of the operation unit;
a display control unit configured to cause the display unit to display a screen in an orientation corresponding to the instruction on the orientation; and
a layout-orientation setting unit configured to set a vertical direction of the function layout of the operation unit to match a vertical direction of the display by the display unit.

2. The flow-rate measuring device according to claim 1,
wherein the display unit and the operation unit are disposed as separate components in regions that differ from each other.

3. The flow-rate measuring device according to claim 1,
wherein the display unit and the operation unit are constituted by one component having both a display function and an input function.

4. The flow-rate measuring device according to claim 1,
wherein the display control unit is capable of setting the orientation of the display by the display unit in units of 90° and is only allowed to set such that a flow direction of the fluid is opposite to the vertical direction of the display and such that the vertical direction of the display is orthogonal to the flow direction of the fluid.

5. The flow-rate measuring device according to claim 1,
wherein an opening on an inlet side of the flow path and an opening on an outlet side of the flow path are provided such that a set orientation in which a flow direction of the fluid is identical to the vertical direction of the display by the display unit is a set orientation that is not recommended in flow-rate measurement.
